(19) United States
(12) Patent Application Publication
(10) Pub. No.: US 2007/0269948 A1
(43) Pub. Date: Nov. 22, 2007

(54) Non-volatile memory array and method of fabricating the same

(76) Inventor: Dirk Manger, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/436,884

(22) Filed: May 19, 2006

(51) Int. Cl. H01L 21/336

(52) U.S. Cl. 438/257; 257/E29.3; 257/E23.168

(57) ABSTRACT

A two-bits-per-cell flash memory cell is based on a localized trapping storage mechanism. The memory cell may be programmed via a hot hole injection mechanism and erased via a Fowler-Nordheim electron tunneling mechanism. The memory cells are arranged according to a virtual-ground wiring scheme. Gate structures of the memory cells are arranged in columns, and the widths of the columns are essentially equal to the distance between the columns. Bit lines elongate in pairs between the columns of memory cells and connect corresponding impurity regions being associated to one of the columns of memory cells. Separation devices separating the bit lines of each pair of bit lines are formed symmetrically to the edges of the neighboring columns of memory cells. Program cross-talk issues, concerning memory cells sharing the same bit line, may be avoided while memory cell size remains essentially unaffected.

### FIELD OF THE INVENTION

The present invention relates to a method of fabricating a memory cell array of a non-volatile memory device. The invention relates further to a method of fabricating a non-volatile memory array having a plurality of non-volatile memory cells that are arranged in columns and to a memory array with non-volatile memory cells and bit lines.

### BACKGROUND

Two-bit flash electrically erasable programmable read only memory devices (EEPROM) comprise a plurality of memory cells that are arranged in a matrix having rows and columns. Nitride-based localized trapping storage flash memory cells are n-MOSFETs with a nitride charge trapping layer sandwiched between two oxide layers as the gate dielectric. The nitride layer functions as an electrical charge trapping medium. Two bits are stored in physically different areas of the charge trapping layer near the two impurity regions of the memory cell. Due to the symmetric access to both bits of the two-bit cell, each impurity region may alternately act as source or drain.

Different types of nitride-based two-bit memory cells differ in the respective program/erase mechanisms. According to a first type of a nitride-based two-bit memory cell, each bit is programmed by channel-hot-electron (CHE) injection, while it is erased by band-to-band tunneling induced hot hole (BTBTHH) injection. Programming and erasing are controlled by applying suitable programming/erasing voltages between a control gate and to either the left or right impurity region of the memory cell. The memory cell is read in the opposite direction from which it was programmed, meaning a read voltage is applied between the control gate and either the right or the left impurity region while the other impurity region is grounded. Programming and reading of one bit leaves the other bit unaffected.

A further nitride-based two-bit flash electrically erasable programmable read only memory device is described in the article entitled “A Novel PHINES Flash Memory Cell with Low Power Program/Erase, Small Pitch, Two-bits-per-cell for Data Storage Applications”, C. C. Yeh, T. Wang, W. J. Tsai et al., IEEE Transactions on Electron Devices, Vol. 52, No. 4, April 2005. The cell is based on a nitride storage cell structure as described above. The cell uses band-to-band-tunneling induced hot hole injection as a program method, wherein the injected charge lowers the local threshold voltage. Fowler-Nordheim (FN) injection is used as an erase mechanism, such that electrons are injected from the control gate through the top oxide into the storage layer and compensate the positive charge being previously stored therein.

As both impurity regions of each memory cell may act both as source or drain and as each memory cell is symmetrical with regard to both bits, the bit lines connecting corresponding impurity regions of the memory cell are typically arranged in a symmetrical virtual-ground array. According to a conventional virtual-ground array wiring scheme, two adjacent columns of memory cells share one common bit line.

The holes generated during a program cycle in vicinity of an impurity region being shared between adjacent memory cells, however, may not completely be injected into the trapping layer of the addressed memory cell, but may migrate also in direction of the neighboring, non-selected memory cell sharing the same impurity region and the same word line, such that they may be injected into the trapping layer of the neighboring memory cell. A program malfunction or program cross-talk between neighboring memory cells sharing the same bit line and the same word line may therefore occur.

Conventionally, avoiding a disturbance of adjacent memory cells during a program cycle requires a biasing of non-selected adjacent bit lines. However, due to voltage drops, the application of an inhibit-bias may not work reliably in a larger array or may activate a further injection mechanism in non-selected but biased memory cells. An inhibit-bias on adjacent bit lines may also result in a higher voltage stress to which an isolation oxide between adjacent bit lines or between a bit line and a crossing word line must withstand.

### SUMMARY

In a first aspect, the present invention provides a method of forming a non-volatile memory array. A plurality of non-volatile memory cells is provided, wherein each memory cell is capable of storing charge in two separated and separately controllable locations. The non-volatile memory cells are arranged in columns that extend in a column direction. The columns have a line width and a line distance to each other, wherein the line distance is essentially equal to the line width. Pairs of bit lines are provided, wherein each pair of bit lines is located between a pair of neighboring columns of memory cells. Each bit line connects the memory cells of one of the columns of memory cells and extends along the column direction. Separation devices are provided that separate in each case the bit lines of one of the pairs of bit lines. The separation devices are in each case adjusted symmetrically to apposing edges of a respective pair of neighboring columns of memory cells.

According to an exemplary embodiment, a plurality of connectivity lines is formed between the columns of memory cells. Each connectivity line extends along the column direction and connects memory cells being arranged in two neighboring columns of memory cells. The connectivity lines are in each case split up along the column direction in two neighboring bit lines, wherein each bit line connects the memory cells of one of the columns of memory cells.

Thus, a program cross-talk issue inherent to a virtual-ground wiring scheme for two-bit non-volatile memory cells basing on a band-to-band tunneling induced hot hole injection mechanism may be avoided. Holes generated during programming or during an erase-cycle are unambiguously assigned to the selected memory cell. The application of an inhibit-bias voltage that may result in a higher voltage stress of insulator structures or that may activate a further injection mechanism in non-selected memory cells can be avoided, whereas the size of the memory cell remains unaffected.

In a second aspect the present invention provides a method of forming an array of non-volatile memory cells, wherein a plurality of gate structures is provided on a pattern surface of a semiconductor substrate. The gate structures are arranged in columns extending along a column direction, wherein the columns have a line width and a line distance to each other being essentially equivalent to the line width. Each gate structure is associated with one of the memory cells and comprises a control gate and a storage element that is capable of storing electric charge in two separated and separately controllable locations.

Pairs of bit lines are provided between each pair of neighboring columns of gate structures respectively, wherein each bit line extends along the column direction and connects impurity regions of memory cells being associated with one of the neighboring columns of gate structures. Separation devices are provided that separate in each case the bit lines of one of the pairs of bit lines and that are in each case adjusted symmetrically to opposing edges of the respective pair of neighboring columns of memory cells.

According to an exemplary embodiment, between each pair of neighboring columns of gate structures one connectivity line is formed, wherein each connectivity line extends along the column direction and connects the impurity regions of the memory cells that are associated with the respective pair of neighboring columns of gate structures. Each connectivity line is split up along the column direction in a pair of neighboring bit lines, wherein each bit line connects the impurity regions associated with one of the columns of gate structures.

As the number of holes migrating undirected between adjacent memory cells is significantly reduced, a bias voltage applied to adjacent bit lines may be reduced. The voltage stress of an insulator structure separating neighboring bit lines or a word line and a crossing bit line may be significantly reduced. The requirement for biasing neighboring memory cells may be completely omitted.

In a further aspect, the present invention provides a non-volatile memory cell array including a plurality of non-volatile memory cells being capable of storing charge in two separated and separately controllable locations. The memory cells are arranged in columns extending along a column direction. The columns have a line width and a line distance to each other, wherein the line distance is essentially equal to the line width. The memory cell array includes further a plurality of bit lines, wherein in each case one pair of bit lines is arranged between two neighboring columns of memory cells and wherein each bit line connects the memory cells of one of the columns of memory cells.

According to a further aspect, the invention provides a non-volatile memory cell array including a plurality of memory cells comprising in each case a gate structure, a first impurity region and a second impurity region. The first and second impurity regions are formed within a semiconductor substrate and are separated by a channel region. The gate structure is in each case arranged above the channel region and comprises a control gate and a storage element being capable of storing electric charge in two separated and separately controllable locations. The gate structures are disposed on a pattern surface of the semiconductor substrate and are arranged in columns extending along a column direction. The columns have a line width and a line distance to each other being essentially equivalent to the line width. The memory cell array includes further a plurality of bit lines, wherein in each case one pair of bit lines is arranged between two neighboring columns of gate structures. Each bit line connects the impurity regions associated with one of the columns of gate structures.

As an inhibit-bias voltage on neighboring word lines and bit lines may be reduced or completely omitted, a voltage stress to which insulating structures between neighboring bit lines, or between crossing word lines and bit lines must withstand is reduced and an undesired programming or erasing of non-selected memory cells caused by the inhibit-bias is avoided. The size of the memory cell remains unaffected.

The above and still further features and advantages of the present invention will become apparent upon consideration of the following definitions, descriptions and descriptive Figures of specific embodiments thereof, wherein like reference numerals in the various Figures are utilized to designate like components. While these descriptions going to specific details of the invention, it should be understood that variations may and do exist and would be apparent to the person skilled in the art based on the description therein.

### BRIEF DESCRIPTION OF THE DRAWINGS

The disclosure will present in detail the following description of exemplary embodiments with reference to the following Figures.

FIG. 1 is a schematic top view of a plurality of memory cells arranged according to a conventional virtual-ground wiring scheme.

FIG. 2A-2F illustrate a method for manufacturing a non-volatile memory cell array according to a first embodiment of the present invention via simplified cross-sectional views of a section of a memory cell array with nitride-based non-volatile memory cells in different stages of processing.

FIG. 3 is a simplified cross-sectional view of a section of a non-volatile memory cell array with nitride-based memory cells according to a further embodiment of the invention.

FIG. 4A-4D illustrate a method for manufacturing a non-volatile memory cell array according to another embodiment of the present invention via simplified cross-sectional views of a section of a memory cell array with nitride-based non-volatile memory cells in different stages of processing.

FIG. 5A-5G illustrate a method for manufacturing a non-volatile memory cell array according to a further embodiment of the invention via simplified cross-sectional views.

### DETAILED DESCRIPTION

Corresponding numerals in the different figures refer to corresponding layers, structures and features unless otherwise indicated. The figures are drawn to clearly illustrate the relevant aspects of the exemplary embodiments and are not necessarily in all respects drawn to scale.

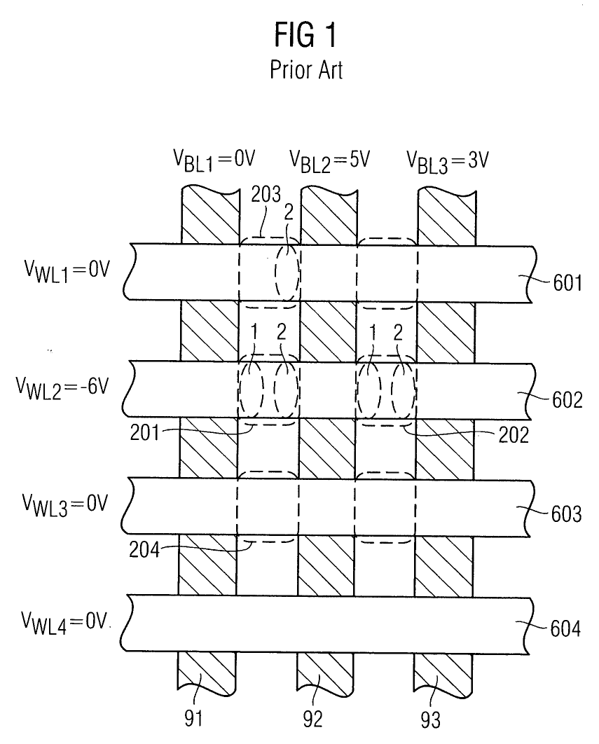

FIG. 1 shows a section of a memory cell array with two-bit non-volatile memory cells being arranged according to a virtual-ground wiring scheme, as for example a “programming by hot hole injection nitride electron storage” (PHINES) memory cell array. A plurality of memory cells is arranged in a matrix having rows and columns. The rows extend horizontally along a word line direction. The columns extend perpendicular to the word line direction in a column direction that corresponds to a bit line direction. Between the columns of memory cells a first, a second and a third bit line 91, 92, 93 are formed. The bit lines 91, 92, 93 connect in each case impurity regions (not shown) of neighboring columns of memory cells.

First, second, third and forth word lines 601, 602, 603, 604 connect in each case control gates (not shown) of memory cells that are arranged along the word line direction. Each memory cell is capable of storing two separated and separately controllable bits 1, 2. A first memory cell 201 and a neighboring second memory cell 202 share the second bit line 92 and are selected by the second word line 602.

Applying a program voltage between the second word line 602 and the respective bit lines 92, 91, triggers programming of bit 2 of the first memory cell 201. By applying a positive voltage on second bit line 92, holes may be generated that may migrate along the word line direction. By band-to-band tunneling induced hot hole injection a part of them is injected into a trapping layer of first memory cell 201, wherein bit 2 of memory cell 201 is programmed. Holes may also migrate in the opposite direction, i.e. to the neighboring second memory cell 202. A part of them may charge by band-to-band tunneling induced hot hole injection bit 1 of memory cell 202. A mis-programming or unintended programming of bit 1 of second memory cell 202 may result. Therefore an inhibit-bias voltage is usually applied to the third bit line 93, wherein the inhibit-bias voltage inhibits or reduces hot hole injection in the region of second memory cell 202.

Holes that are generated in the region of bit 2 of memory cell 201 may also migrate along the column direction such that they may lead to an unintended programming of bit 2 of neighboring memory cells 203, 204 sharing second bit line 92. An inhibit-biasing voltage of for example 0 Volt is therefore typically applied to the unselected word lines 601, 603, 604.

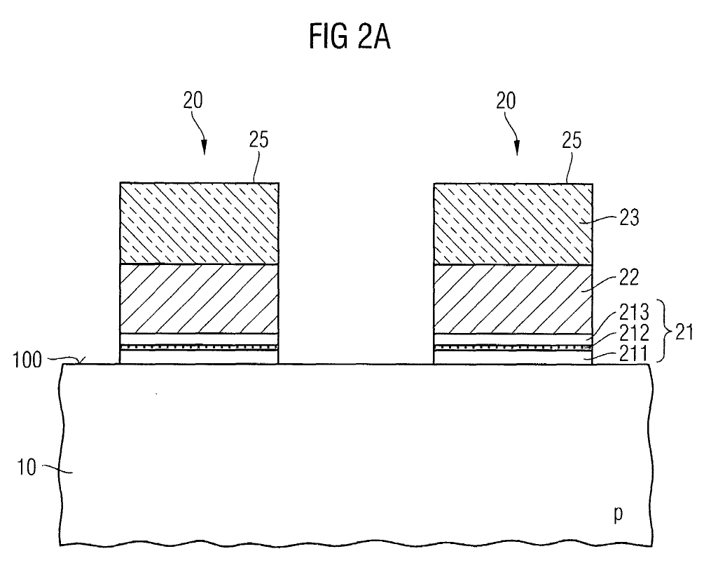

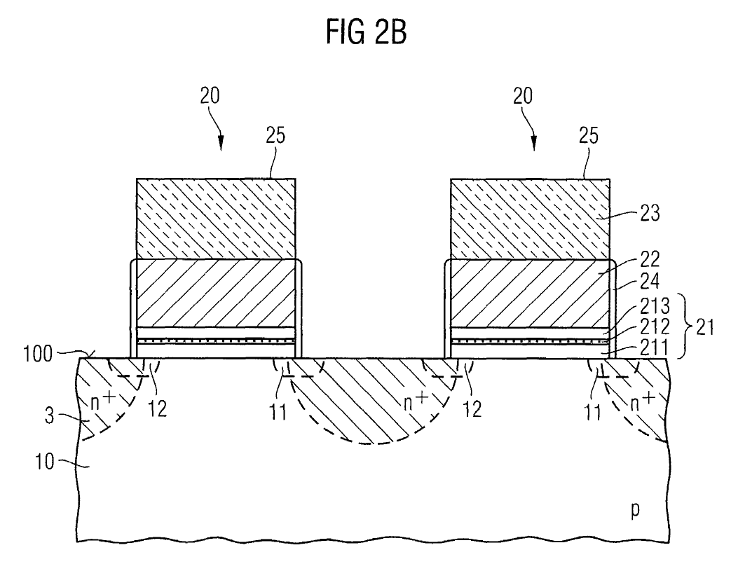

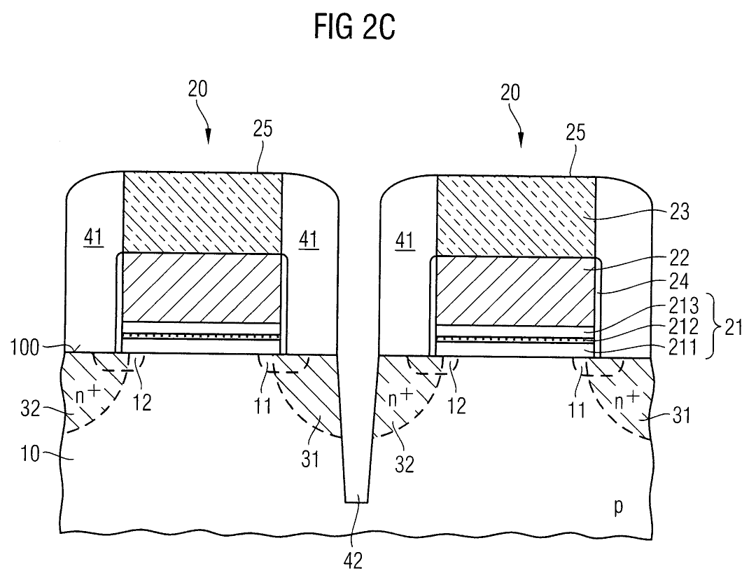

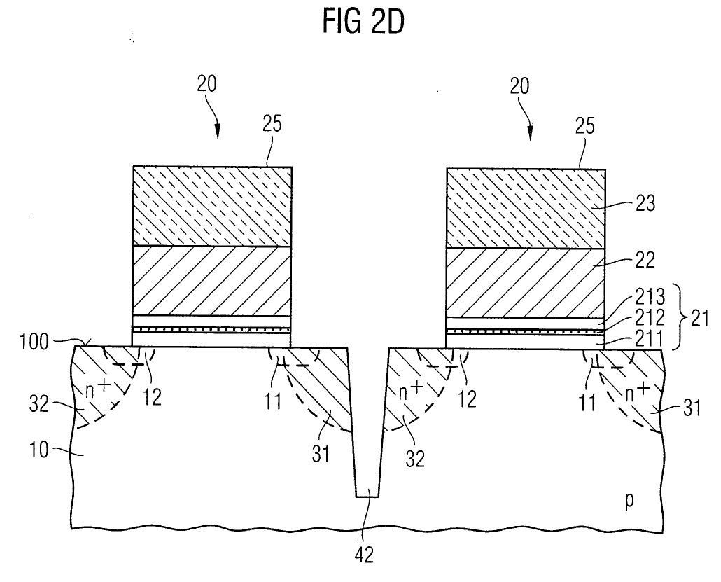

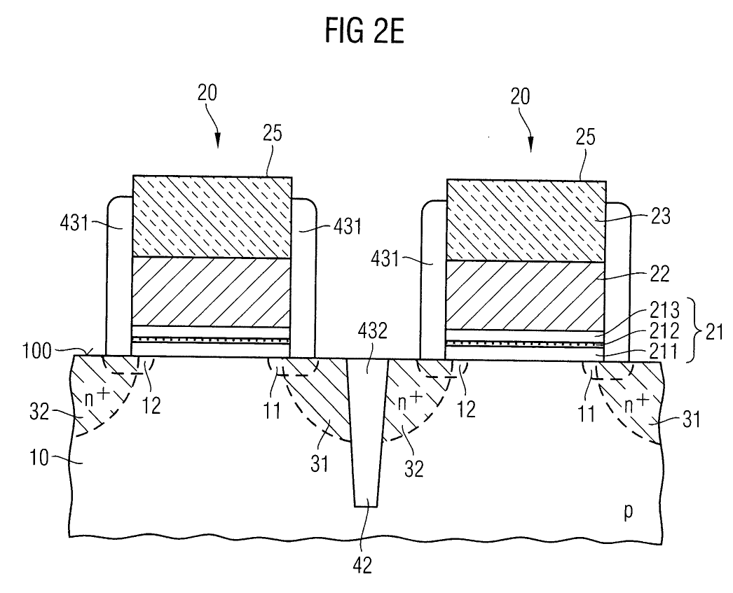

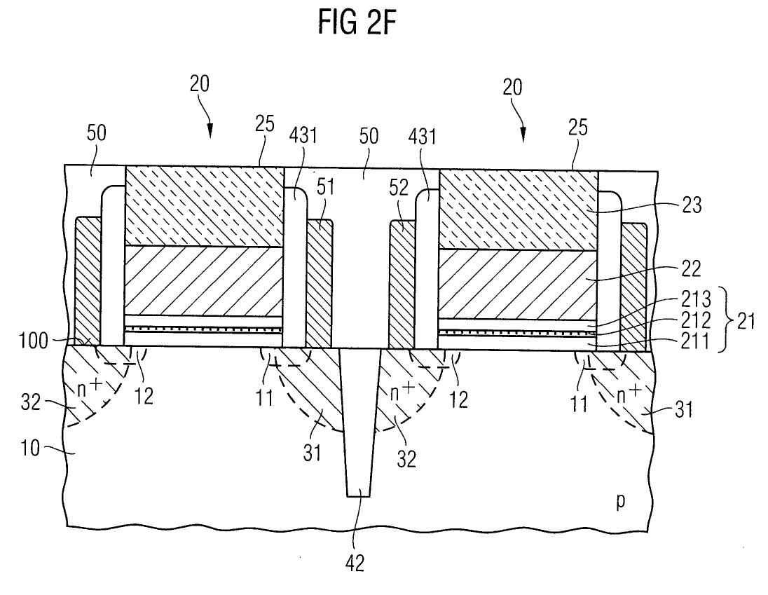

FIG. 2A to 2F illustrate a method of forming split bit lines for a nitride-based non-volatile memory cell array.

Referring to FIG. 2A, first a substrate 10 is provided. Substrate 10 may be a single crystalline semiconductor substrate, such as a silicon wafer. An upper section of the semiconductor substrate 10 may be p-conductive. On a pattern surface 100 of substrate 10 a bottom dielectric layer 211, a trapping layer 212, a top dielectric layer 213, a first gate conductor 22 and a capping layer 23 are successively disposed. A resulting layer stack is patterned by photolithographic means, wherein parallel gate structures 25 are formed. The gate structures 25 extend along a column direction and are separated, a line distance apart from each other, by space. A line distance between neighboring gate structures 25 is essentially equal to a line width of the gate structures 25.

FIG. 2A shows two neighboring gate structures 25 being disposed in each case on pattern surface 100 of substrate 10 and extending in the column direction that is perpendicular to the cross-sectional plane. A space line separates the gate structures 25 from each other. Each gate structure 25 is associated with a memory cell 20.

Each gate structure 25 comprises a bottom dielectric layer 211 adjoining pattern surface 100. Bottom dielectric layer 211 may be of silicon dioxide and may have a thickness of about 4 to 10 Nanometers, for example 6 Nanometers. Trapping layer 212 covers bottom dielectric layer 211. Trapping layer 212 may be of silicon nitride and may have a thickness of 4 to 10 Nanometers, for example 6 Nanometer. Top dielectric layer 213 covers trapping layer 212 and may have a thickness of 6 to 15 Nanometers, for example 9 Nanometer. Top dielectric layer 213 may be of silicon oxide and separates trapping layer 212 from first gate conductor 22. First gate conductor 22 forms at least a section of a control gate (not shown) and may be of doped polycrystalline silicon (polysilicon). The thickness of first gate conductor 22 may be between 20 and 40 Nanometers, for example 35 Nanometers. Capping layer 23 covers first gate conductor 22 and may be of silicon nitride. The width of each gate structure 25 may be between 20 and 100 Nanometers. The width of the space line between neighboring gate structures 25 may be equivalent to the line width of the gate structures ±20%.

Referring now to FIG. 2B, the material of first gate conductor 22 is oxidized in a temper step, wherein a sidewall oxide 24 is formed on lower sections of exposed vertical sidewalls of the gate structures 25.

Through an angled or straight implantation, pocket implants 11, 12 are formed near the edges of the gate structures 25. Via a vertically orientated implantation, connectivity lines 3 are formed between the gate structures 25, wherein the gate structures 25 act as an implantation mask. The pocket implants 11, 12 and in sections the connectivity lines 3 form n⁺-doped impurity regions representing symmetrical source/drain regions of the memory cells.

Referring to FIG. 2C, a sacrificial material is conformably deposited in a thickness that may be at least a third of the width of the space line. For a space line width of about 95 Nanometer, the thickness of the deposited sacrificial liner may be 40 Nanometer. The deposited sacrificial material is TEOS-based silicon dioxide by way of example. Other materials may be PE-silicon nitride and silicon oxynitride SiON. Then an anisotropic spacer etch is performed, wherein horizontal sections of the deposited sacrificial material are removed, and wherein residual vertical sections of the sacrificial material form sidewall spacers 41 that extend along the vertical sidewalls of the gate structures 25.

Then a dry etch step is performed, wherein the sidewall spacers 41 act as an etch mask shielding underlying sections of the buried connectivity lines 3. Deep, tapered split trenches 42 are formed within substrate 10 by the dry etch step. Each split trench 42 is located symmetrically between two neighboring gate structures 25 and extends to a depth in which substrate 10 is p-conductive. Each split trench 42 separates two opposing bit lines 31, 32 resulting from one connectivity line 3.

As shown in FIG. 2D, sidewall spacers 41 are then removed such that the space lines between neighboring gate structures 25 are void again.

Referring to FIG. 2E, another conformal insulating layer is deposited. The deposited layer material may be LPTEOS-based silicon oxide. The conformal insulating layer may be thinner than the sidewall spacers 41. On the other hand, the thickness should be sufficient to fill the split trenches 42 completely. For a spacer width of 95 nanometers and a thickness of the sidewall spacers 41 of about 40 nanometers, the conformal insulating layer may have a thickness of about 20 nanometers.

As shown in FIG. 2E, the conformal insulating layer is etched in a top-bottom direction, such that first residual sections of the conformal insulator layer form in each case spacer insulators 431 extending along the vertical sidewalls of the gate structures 25. Further residual sections of the conformal insulating layer form separation devices in form of split trench fills 432 of the respective split trenches 42. A small over-etch of the conformal insulating layer may be performed, such that in each case an upper edge of the spacer insulators 431 is drawn back from an upper edge of capping layer 23. First gate conductor 22 remains covered by spacer insulators 431 and the split trench fills 432 remain essentially unaffected from the over-etch. The buried bit lines 31, 32 are exposed in sections. A short deglaze may be performed to clean exposed sections of buried bit lines 31, 32.

As illustrated in FIG. 2F, a layer of conductive material is deposited. The thickness of the deposited layer of conductive material and the thickness of spacer insulator 431 may result in the thickness of sidewall spacer 41. For a sidewall spacer 41 having a thickness of 40 nanometers and a spacer insulator 431 having a thickness of 20 nanometers, the thickness of the deposited layer of conductive material may be about 20 nanometers. The conductive material may be doped silicon, WiSi_{X}, TiN or tungsten. A spacer etch is performed that is effective on the conductive material. The spacer etch is selective to silicon nitride and silicon oxide. Horizontal sections of the conductive material are removed. Remaining sections of the conductive material form first and second bit line shunts 51, 52 that extend along the vertical outer sidewalls of spacer insulators 431. Each bit line shunt 51, 52 is connected in each case to the corresponding buried bit line 31, 32.

A further insulator material is deposited that fills a remaining gap between opposing bit line shunts 51, 52. A chemical mechanical polishing process is performed that may stop at the upper edge of capping layer 23.

As shown in FIG. 2F, remaining sections of the deposited insulator material form inter gate stack fills 50, wherein the gaps between neighboring gate structures 25 are filled completely. In the following, word lines (not shown) may be formed according to conventional techniques.

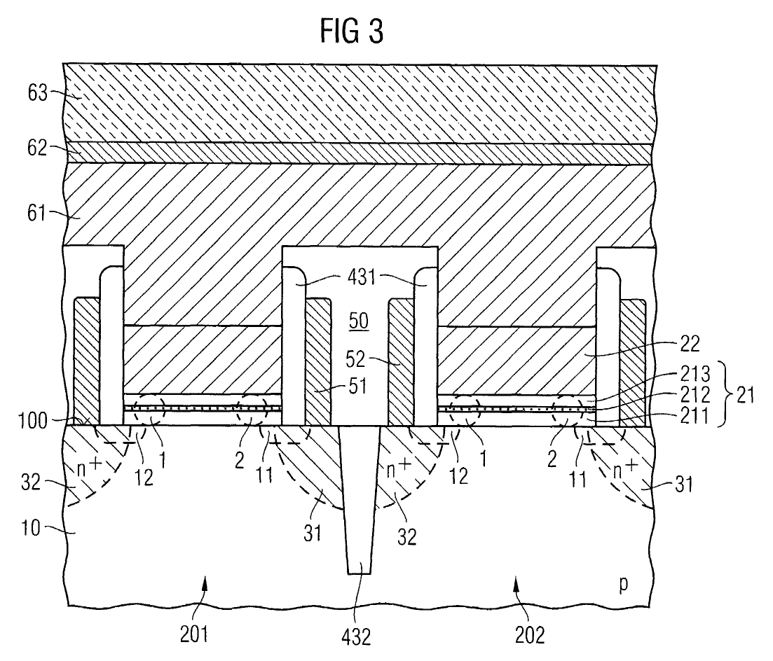

FIG. 3 is a cross-sectional view of two neighboring non-volatile memory cells 201, 202 that are arranged according to a virtual-ground wiring scheme. A first memory cell 201 is illustrated in the left half of FIG. 3 and a second memory cell 202 is illustrated in the right half of FIG. 3.

Each memory cell 201, 202 comprises a gate structure disposed on a pattern surface 100 of a semiconductor substrate 10 and an active area formed within substrate 10 and adjacent to pattern surface 100. Each gate structure comprises an ONO-stack 21 including a bottom dielectric layer 211, a trapping layer 212 and a top dielectric layer 213. Bottom dielectric layer 211 is formed adjacent to pattern surface 100 and insulates trapping layer 212 from substrate 10. Top dielectric 213 insulates trapping layer 212 from a first gate conductor 22. First gate conductor 22 forms a control gate for addressing the respective memory cell 201, 202. Spacer insulators 431 are formed on vertical sidewalls of the respective gate structure.

The active areas of memory cells 201, 202 comprise two n⁺-doped impurity regions formed within substrate 10 on opposing sides of the respective gate structure 25. A p-conductive channel region separates the two impurity regions. Each impurity region comprises a lightly doped pocket implant 11, 12 and a heavily doped diffused impurity region. Each heavily doped impurity region is a section of a first or a second buried bit line 31, 32 that extend along a column direction perpendicular to the section plane. Each first and second bit line 31, 32 connects a plurality of impurity regions of a column of memory cells, wherein the memory cells are arranged in a matrix having columns and rows.

Each pair of first 31 and second 32 buried bit line emerge from one contiguous impurity line that is split up by an etch and a subsequent insulator fill process. From the fill process, split trench fills 432 result that form separation devices separating in each case the first 31 and the second 32 buried bit line of one of the pairs of first 31 and second 32 bit lines. Along the vertical outer sidewalls of spacer insulator 431 first and second bit line shunts 51, 52 of a high conductivity material such as heavily doped polysilicon, a metal, a metal nitride or metal silicide extend along the columns of memory cells. Each bit line shunt 51, 52 adjoins pattern surface 100 in a section in which the respective buried bit line 31, 32 is formed within substrate 10 such that each bit line shunt 51, 52 is electrically connected to the respective buried bit line 31, 32. An inter gate stack fill 50 separates opposing bit line shunts 51, 52.

Word lines 6 comprise in each case a second gate conductor 61, a high conductivity layer 62 covering second gate conductor 61, and a word line cap 63 covering high conductivity layer 62 and extend perpendicular to the column direction. Each word line 6 connects the control gates 22 of a plurality of memory cells 201, 202 that are arranged along a row of memory cells. Word lines 6 are line-shaped. Adjacent word lines 6 are separated by insulating inter word line fills (not shown).

Each memory cell 201, 202 is capable of storing electric charge in two separated and separately controllable trapping sections 1, 2. Bit 1 is programmed by applying a positive programming voltage between second buried bit line 32 and control gate 22, wherein a band-to-band tunnel induced injection of hot holes generated near second buried bit line 32 is enabled.

Programming of bit 2 is performed by applying a programming voltage between first buried bit line 31 (positive) and control gate 22 (negative) accordingly. As the holes are generated only in vicinity of the respective buried bit line 31, the neighboring second memory cell 202 remains unaffected. Migration of holes from first buried bit line 31 to second memory cell 202 is essentially suppressed. The size of the memory cell array remains unaffected. Neighboring first and second buried bit lines 31, 32 are switched to different sensing/driving stages or to the same sensing/driving stages at different times.

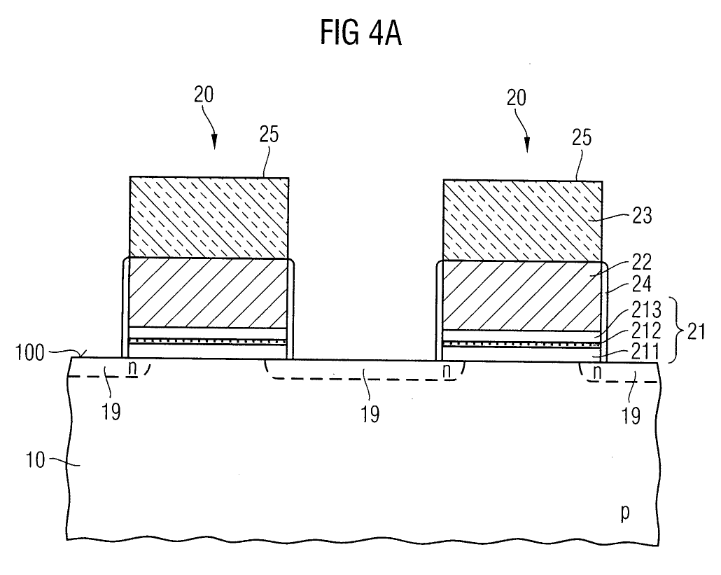

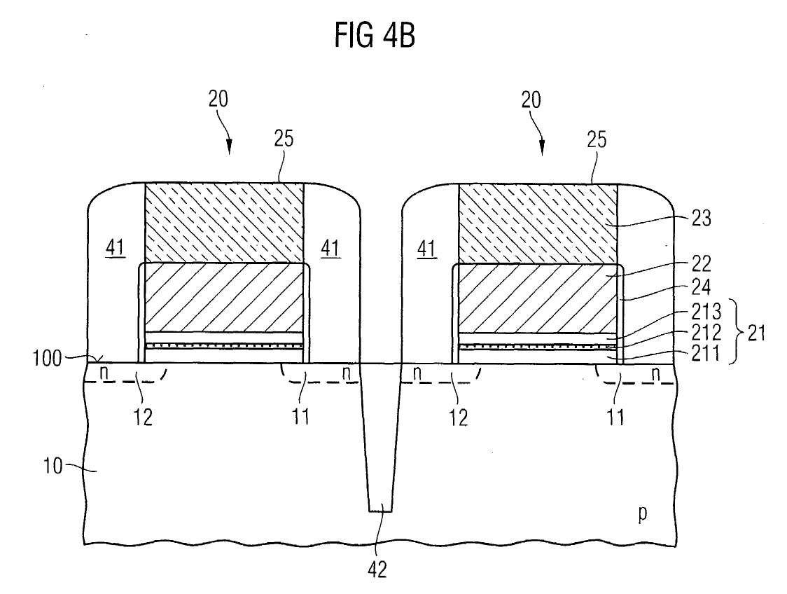

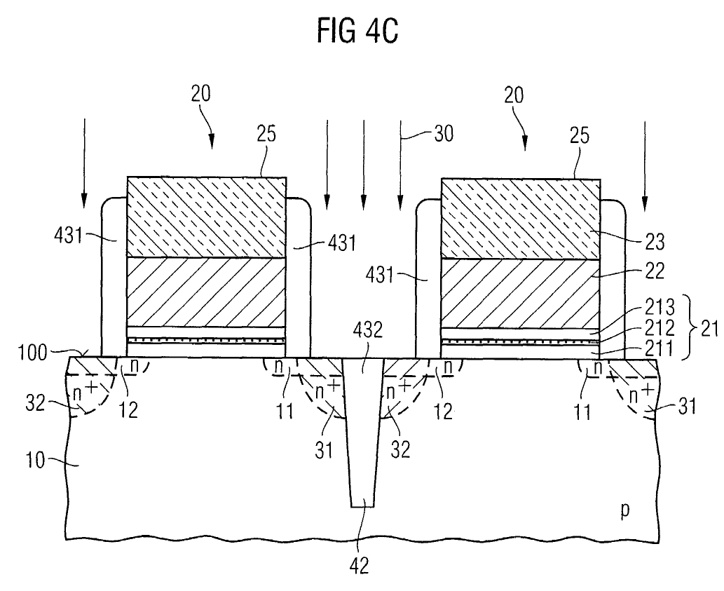

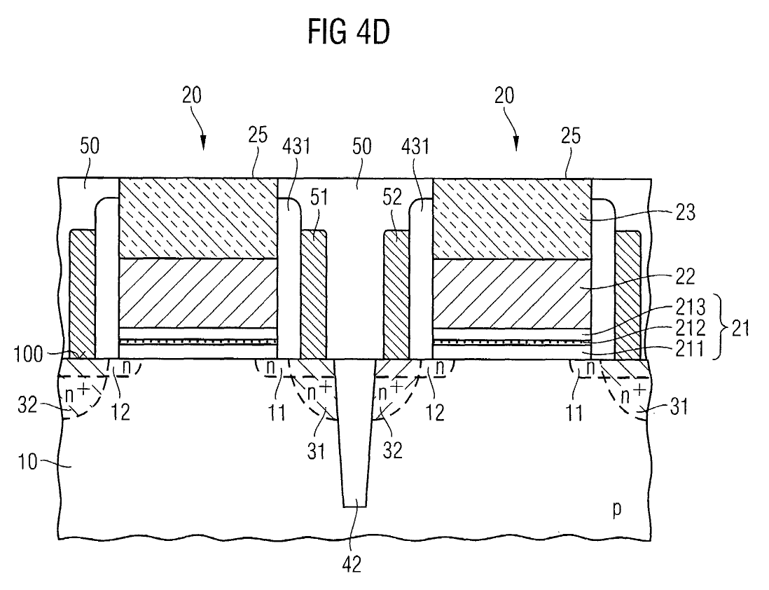

FIG. 4A to FIG. 4B illustrate a further method of forming the bit lines and the separation devices, wherein the order of implantation and etch process is altered.

FIG. 4A follows FIG. 2A, wherein a sidewall oxide 24 is formed on lower sections of exposed vertical sidewalls of the gate structures 25. Between each pair of neighboring gate structures 25 one joint pocket implant 19 is formed through a vertical orientated implantation. Each joint pocket implant 19 forms a continuous n-doped impurity region in upper sections of substrate 10 beneath the space lines.

Referring to FIG. 4B sidewall spacers 41 are formed, that extend along the vertical sidewalls of gate structures 25 as described above with regard to FIG. 2C. A separation device is formed through a dry etch step, wherein sidewall spacers 41 and gate structures 25 act as an etch mask and shield underlying sections of the buried joint pocket implant 19. Deep, tapered split trenches 42 within substrate 10 emerge from the dry etch step. Each split trench 42 is adjusted symmetrically to the edges of the two neighboring gate structures 25. From each joint pocket implant 19 two separated pocket implants 11, 12 emerge, wherein each single pocket implant 11, 12 is assigned to one of the gate structures 25.

As illustrated in FIG. 4C, sidewall spacers 41 are then removed and another conformal insulating layer is deposited, wherein split trenches 42 are filled with the insulating material. The filled split trenches 42 form separation devices 432. The conformal insulating layer is etched in a top-bottom direction, such that spacer insulators 431 emerge from the conformal insulator layer. Spacer insulators 431 extend along the vertical sidewalls of the gate structures 25 and are thinner than the sidewall spacers 41 were. Sections of the buried pocket implants 11, 12 between the outer edges of spacer insulator 431 and separation device 432 remain exposed. A heavy dose vertical bit line implant 30 is performed, wherein spacer insulator 431 shields sections of the low doped pocket implants 11, 12 near the respective gate structure 25. Buried bit lines 31, 32 are formed through the bit line implant 30 on both sides of separation device 42, wherein the thickness of spacer insulators 431 determine the distance between the gate electrode 25 and the buried bit lines 31, 32.

Referring to FIG. 4D, bit line shunts 51, 52 may be provided as described above.

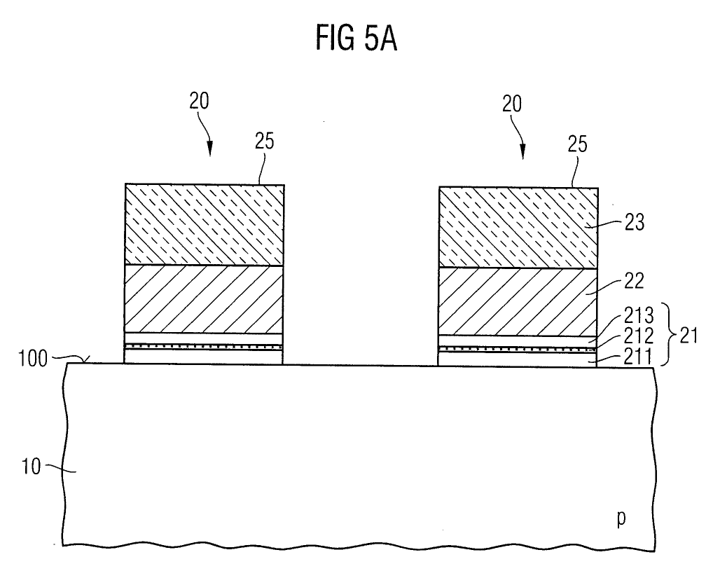

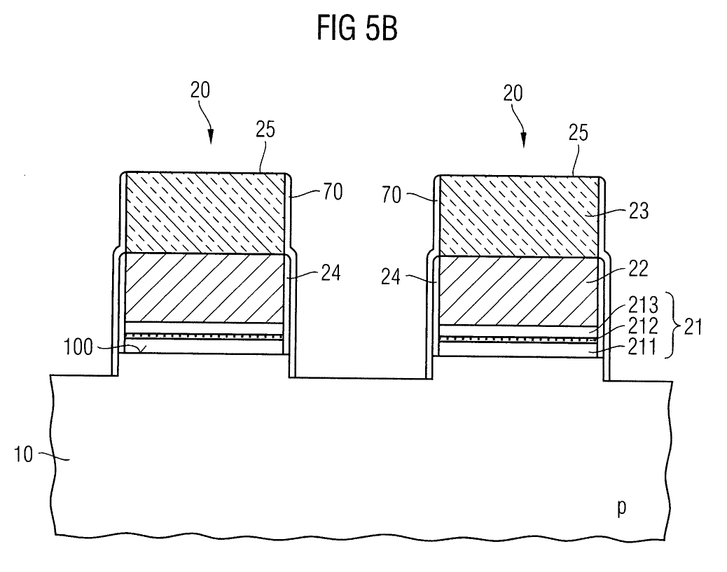

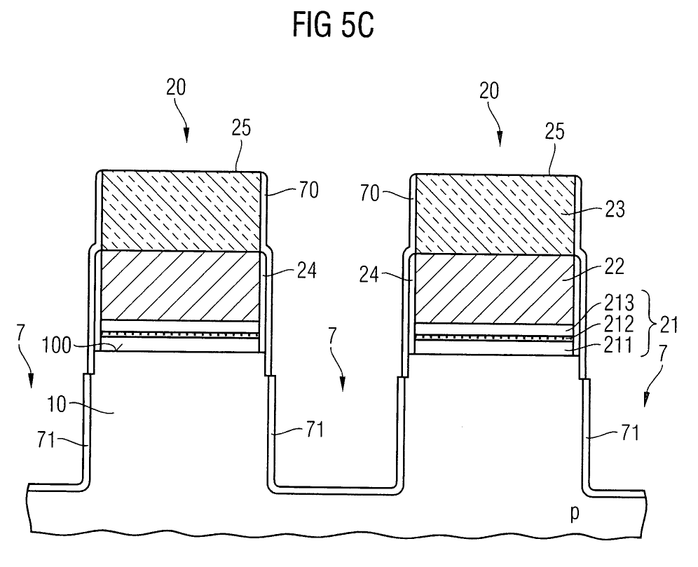

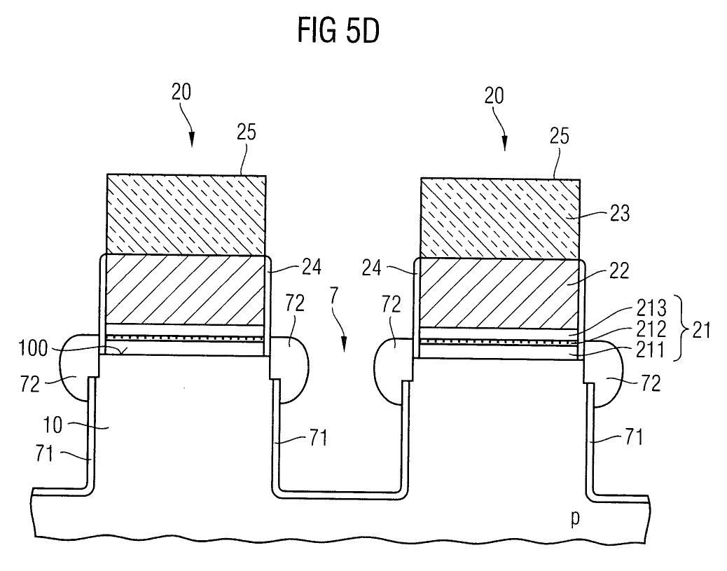

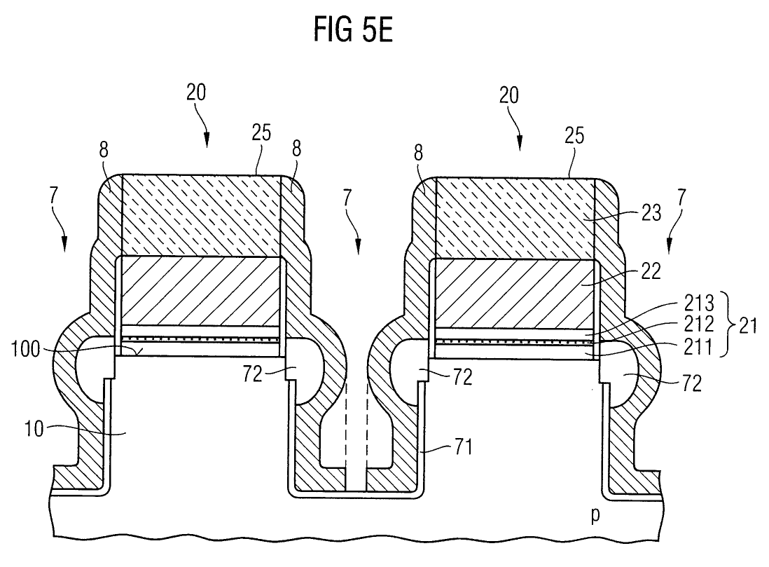

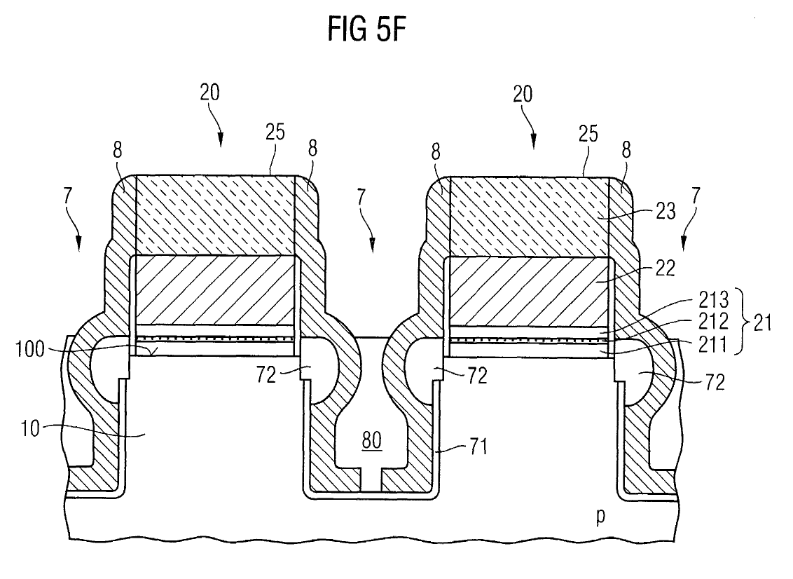

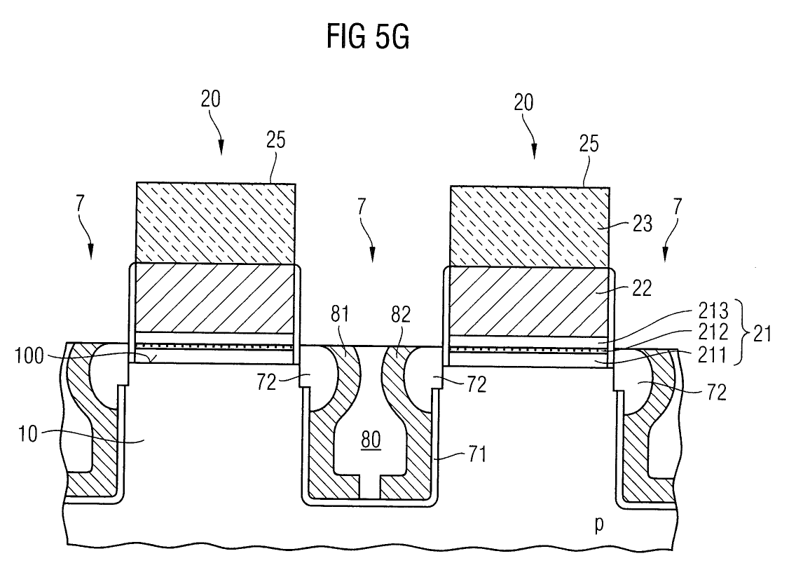

Referring to FIG. 5A to 5G, a further method is described by means of cross-sectional views illustrating two neighboring memory cells 20 in course of processing.

FIG. 5A corresponds to FIG. 2A and shows gate structures 25 of two adjacent memory cells 20. Each gate structure 25 comprises an ONO-stack 21 including a nitride-based trapping layer 212 sandwiched between a bottom dielectric layer 211 and a top dielectric layer 213. Bottom dielectric layer 211 insulates trapping layer 212 from a semiconductor substrate 10 and top dielectric layer 213 separates trapping layer 212 from a first gate conductor 22 representing at least a section of a control gate. In this stage of processing, a capping layer 23 covers gate conductor 22, which typically consists of silicon nitride. The gate structures 25 have a width of about 95 Nanometers or less and the distance between two adjacent gate structures 25 is essentially identical to the width of the gate structures 25.

As shown in FIG. 5B a thermal oxide forms a sidewall oxide 24 that covers exposed vertical sidewalls of gate conductor 22. Sidewall oxide 24 is grown selectively on exposed vertical sidewalls of first gate conductor 22 by thermal oxidation. The thickness of sidewall oxide 24 may be 5 Nanometers. An anisotropic etch is performed that is effective on the silicon of substrate 10, wherein the gate structures 25 act as an etch mask. Between the gate structures 25, the substrate is etched back to a depth of a few Nanometers. The depth of the resulting shallow grooves may be about 10 Nanometers.

A thin silicon nitride liner is deposited and opened by a spacer etch. The thickness of the thin silicon nitride liner may be 7 Nanometers. Horizontal sections of the thin silicon nitride liner are removed. Vertical sections of the thin silicon nitride liner form a pre-etch liner 70 covering vertical sidewalls of the gate structures 25 and of the shallow grooves.

Referring to FIG. 5C, an anisotropic silicon etch is performed that is selective to silicon nitride. Deep grooves 7 are formed between two adjacent gate structures 25 respectively. The depth of the deep grooves 7 is determined by the specified (predetermined) resistance that should be obtained for the buried bit lines. A thermal oxidation is performed such that an insulator oxide 71 lines a bottom portion of the deep grooves 7. FIG. 4C illustrates further silicon nitride pre-etch liner 70 covering an upper portion of each deep groove 7. The thickness of the insulator oxide 71 may be about 5 Nanometers. The depth of the deep grooves 7 may be 50 Nanometers and more.

Referring to FIG. 5D, a liner deglaze is performed. Pre-etch liner 70 may be removed by a THF 2 nm oxide equivalent removal and a hot phosphoric acid 10 nm silicon nitride equivalent removal. By removal of pre-etch liner 70, the upper portion of the deep grooves 7 is exposed. The exposed sections of substrate 10 are cleaned via a THF chemistry. Then silicon is epitaxially grown selectively on the exposed sections of substrate 10 to a target thickness. The target thickness may be about a third of the space line width.

FIG. 5D shows the silicon extensions 72 adjoining previously exposed sections of substrate 10 in the upper portion of each deep groove 7, wherein the upper portion corresponds to the shallow groove formed before deposition of pre-etch liner 70.

The extensions 72 may in each case form at least in sections an impurity regions of the respective memory cell 20.

As illustrated in FIG. 5E a conformal conductive liner is deposited. The conformal conductive liner may consist of heavily doped polysilicon, titan nitride, tungsten, another metal or conductive metal compound or a combination of them. The thickness of the conductive liner is selected such that a void remains between opposing sections of the conductive liner in the upper section of the deep grooves 7. A spacer etch is performed, such that horizontal sections of the conductive liner on top of capping liner 23 are removed and such that in each deep groove 7 the conductive liner is split up into two separate conductive lines 8.

According to FIG. 5F, a conformal or hyper conformal divot fill is performed, wherein an insulator material such as silicon dioxide, LPTEOS-based silicon oxide or a spin-on dielectric with high electric breakdown strength is deposited forming an inter bit line fill 80 filling the gaps between opposing conductive lines 8. Inter bit line fill 80 is recessed to a lower edge of first gate conductor 22. The recess of inter bit line fill 80 may be self-aligned to the pinching level of the conductive lines 8, wherein the pinching level results from the epitaxial grown silicon sections 72.

Referring to FIG. 5G, exposed upper sections of conductive lines 8 are removed selectively with respect to inter bit line fill 80.

Thus highly conductive, self-aligned first and second 81, 82 bit lines are formed between adjacent gate structures 25.

While the invention has been described in detail with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and equivalence.

List of reference signs

| | |
|---|---|
| 1 | bit 1 |
| 2 | bit 2 |
| 3 | connectivity line |
| 8 | conductive line |
| 10 | substrate |
| 11 | pocket implant |
| 12 | pocket implant |
| 19 | joint pocket |
| 20 | memory cell |
| 21 | ONO-stack |
| 22 | first gate conductor |
| 23 | capping layer |
| 24 | sidewall oxide |
| 30 | bit line implantation |
| 31 | first bit line |
| 32 | second bit line |
| 41 | sidewall spacer |
| 42 | split trench |
| 50 | inter gate stack fill |
| 51 | first bit line shunt |
| 52 | second bit line shunt |
| 61 | second gate conductor |
| 62 | high conductivity layer |
| 63 | word line cap |
| 70 | pre-etch liner |
| 71 | insulator oxide |
| 72 | extension |
| 80 | inter bit line fill |
| 81 | first bit line |
| 82 | second bit line |
| 91 | bit line 1 |
| 92 | bit line 2 |
| 93 | bit line 3 |
| 100 | pattern surface |
| 201 | memory cell 1 |
| 202 | memory cell 2 |
| 203 | memory cell 3 |
| 204 | memory cell 4 |
| 211 | bottom dielectric layer |
| 212 | trapping layer |
| 213 | top dielectric layer |
| 431 | spacer insulator |
| 432 | split trench fill |
| 601 | first world line |
| 602 | second world line |
| 603 | third world line |
| 604 | forth world line |

What is claimed is:

1. A method of forming an array of non-volatile memory cells, comprising:
providing a plurality of non-volatile memory cells capable of storing charge in two separated and separately controllable locations, the memory cells being arranged in columns extending along a first direction, the columns having a line width and a line distance to each other, wherein the line distance is substantially equal to the line width;
providing pairs of bit lines, wherein individual bit lines extend along the first direction and connect the memory cells of one of the columns of memory cells, and wherein individual pairs of bit lines are disposed between a pair of neighboring columns of memory cells; and
providing separation devices that separate the bit lines of one of the pairs of bit lines and that are symmetrically adjusted to opposing edges of a respective pair of neighboring columns of memory cells.

2. The method of claim 1, wherein the line distance is equivalent to the line width.

3. The method of claim 1, wherein:
a plurality of connectivity lines is formed, at least one connectivity line being located between a pair of neighboring columns of memory cells, extending along the first direction and connecting memory cells arranged in respective two neighboring columns of memory cells; and
the bit lines are provided by splitting the connectivity lines along the first direction into two neighboring bit lines respectively.

4. The method of claim 3, wherein the connectivity lines are formed as impurity lines within a semiconductor substrate, the impurity lines forming in sections first impurity regions of one of the neighboring columns of memory cells and second impurity regions of the other neighboring column of memory cells.

5. The method of claim 4, wherein the connectivity lines are split via an etching process.

6. A method of forming an array of non-volatile memory cells, comprising:
providing a plurality of gate structures on a pattern surface of a semiconductor substrate, the gate structures being arranged in columns extending along a first direction, the columns having a line width and having a line distance to each other that is substantially equivalent to the line width, wherein individual gate structures are associated with one of the memory cells and comprise a control gate and a storage element capable of storing electric charges in two separated and separately controllable locations;
providing pairs of bit lines between each pair of neighboring columns of gate structures respectively, wherein individual bit lines extend along the first direction and connect impurity regions of memory cells associated with one of the neighboring columns of gate structures; and
providing a separation device that separates the bit lines of one of the pairs of bit lines and that is symmetrically adjusted to opposing edges of the respective pair of neighboring columns of memory cells.

7. The method of claim 6, wherein the line distance is equivalent to the line width.

8. The method of claim 6, wherein:
connectivity lines are formed between each pair of neighboring columns of gate structures, wherein individual connectivity lines extend along the first direction and connect the impurity regions of memory cells associated with the respective pair of neighboring columns of gate structures; and
the bit lines are provided by splitting the connectivity lines along the first direction into a pair of neighboring bit lines, wherein individual bit lines connect the impurity regions associated with one of the columns of gate structures.

9. The method of claim 8, wherein splitting the conductivity lines comprises:
forming sidewall spacers that are elongated along vertical sidewalls of the gate structures;
etching split trenches into the semiconductor substrate, wherein the sidewall spacers and the gate structures act as an etch mask; and
providing insulating split trench fills in the split trenches.

10. The method of claim 9, further comprising:
removing the sidewall spacers;
providing spacer insulators that are elongated along the vertical sidewalls of the gate structures and being thinner than the sidewall spacers, wherein the bit lines remain exposed in sections;
depositing a conformal high conductivity layer that adjoins the exposed sections of the bit lines; and
anisotropically etching the conformal high conductivity layer, such that horizontal sections of the conformal layer are removed and at least one residual vertical section of the conformal layer forms a bit line shunt connected to the respective bit line.

11. The method of claim 8, wherein the forming and splitting of the connectivity lines comprises:
etching grooves into the semiconductor substrate between neighboring gate structures, such that individual grooves have a lower and an upper portion;
forming an insulator layer lining in the lower portion of the grooves;
depositing a conformal conductive layer forming a plurality of joint connectivity lines; and
performing a spacer etch that is effective on the connectivity lines, wherein remaining sections of the connectivity lines form pairs of bit lines that are elongated on opposing sidewalls of the respective groove.

12. The method of claim 11, wherein, before the deposition of the conformal conductive layer, the upper portion of the groove is exposed and extensions are formed via epitaxial growth on exposed sections of the substrate, such that individual extensions form at least a section of one of the impurity regions.

13. The method of claim 12, wherein:
the upper portions of the grooves are formed via a first etch step;
a pre-etch liner is provided that covers vertical sidewalls of the gate structures and the upper portions of the grooves;
the lower portions of the grooves are formed via a second etch step, wherein the pre-etch liner shields the upper portions of the grooves; and
the upper portions of the grooves are exposed by removing the pre-etch liner.

14. The method of claim 6, wherein the storage element is provided via disposing a bottom dielectric layer on the pattern surface, disposing a trapping layer on the bottom dielectric layer and disposing a top dielectric layer on the trapping layer.

15. The method of claim 14, wherein the memory cells are capable of being programmed via band-to-band tunneling induced hot hole injection.

16. The method of claim 15, wherein the memory cells are capable of being erased via electron tunneling from the control gate to the storage layer.

17. The method of claim 6, wherein providing the pairs of bit lines and the separation devices, comprises:
forming sidewall spacers that are elongated along vertical sidewalls of the gate structures;
etching split trenches into the semiconductor substrate, wherein the sidewall spacers and the gate structures act as an etch mask;
providing insulating split trench fills in the split trenches; and
forming the bit lines via implantation on both sides of the split trenches.

18. The method of claim 17, wherein low doped pocket implants are formed prior to formation of the sidewall spacers.

19. The method of claim 17, subsequently comprising:
removing the sidewall spacers;
providing spacer insulators that are elongated along the vertical sidewalls of the gate structures and being thinner than the sidewall spacers, wherein the bit lines remain exposed in sections;
depositing a conformal high conductivity layer that adjoins the exposed sections of the bit lines; and
anisotropically etching the conformal high conductivity layer, such that horizontal sections of the conformal layer are removed and at least one residual vertical section of the conformal layer forms a bit line shunt connected to the respective bit line.

20. A non-volatile memory cell array comprising:
a plurality of non-volatile memory cells capable of storing charge in two separated and separately controllable locations, the memory cells being arranged in columns extending along a first direction, the columns having a line width and a line distance to each other, wherein the line distance is substantially equal to the line width; and
a plurality of bit lines, wherein pairs of bit lines are disposed between two neighboring columns of memory cells and wherein individual bit lines connect the memory cells of one of the columns of memory cells.

21. The memory cell array of claim 20, wherein individual bit lines are formed from one impurity line being formed within a semiconductor substrate and wherein individual bit lines form, in sections, impurity regions of the memory cells of one of the columns of memory cells.

22. The memory cell array of claim 21, further comprising split trench fills that separate the bit lines of one of the pairs of bit lines.

23. The memory cell array of claim 22, further comprising bit line shunts comprising a high conductivity material and being elongated parallel and adjacent to a respective bit line.

24. A non-volatile memory cell array, comprising:
a plurality of memory cells comprising a gate structure, a first impurity region, and a second impurity region, the first and second impurity regions being formed within a semiconductor substrate and being separated by a channel region, the gate structure being disposed above the channel region and comprising a control gate and a storage element capable of storing electric charges in two separated and separately controllable locations, and the gate structure being disposed on a pattern surface of the semiconductor substrate and being arranged in columns extending along a first direction, the columns having a line width and having a line distance to each other that is substantially equivalent to the line width; and
a plurality of bit lines, wherein pairs of bit lines are arranged between two neighboring columns of gate structures, and wherein individual bit lines connect the impurity regions associated with one of the columns of gate structures.

25. The memory cell array of claim 24, wherein the line distance is equivalent to the line width.

26. The memory cell array of claim 25, wherein the storage element comprises a nitride based trapping layer separated from the semiconductor substrate by a bottom dielectric layer and separated from the control gate by a top dielectric layer.

27. The memory cell array of claim 26, wherein the memory cells are capable of being programmed via band-to-band tunneling induced hot hole injection.

28. The memory cell array of claim 27, wherein the memory cells are capable of being erased via electron tunneling from the control gate to the storage element.

29. The memory cell array of claim 24, wherein individual bit lines are formed as an impurity line and form, in sections, parts of the associated impurity regions.

30. The memory cell array of claim 29, further comprising bit line shunts comprising a high conductivity material and being elongated parallel and adjacent to one of the bit lines.

31. The memory cell array of claim 24, wherein individual bit lines comprise a high conductivity material and are disposed between neighboring columns of memory cells.

32. The memory cell array of claim 31, further comprising epitaxial grown extensions disposed between the bit lines and the substrate and forming at least a section of one of the impurity regions.
